(19) United States
(12) Patent Application Publication
(10) Pub. No.: US 2026/0271724 A1
(43) Pub. Date: Sep. 10, 2026

(54) MICRO-ELECTROMECHANICAL SYSTEMS (MEMS) DEVICES

(71) Applicant: Taiwan Semiconductor Manufacturing Company, LTD., Hsinchu (TW)

(72) Inventor: Yu-Hsun Li, Yunlin (TW)

(21) Appl. No.: 19/073,306

(22) Filed: Mar. 7, 2025

(51) Int. Cl. H01L 23/427; H01L 23/498

(52) U.S. Cl. CPC H10W 40/73; H10W 70/635; H10W 90/701

(57) ABSTRACT

Micro-electromechanical systems (MEMS) devices that include a carrier wafer are disclosed, along with their use for cooling heat-generating devices using dielectric liquids. The MEMS device includes an actuator bonded to a carrier wafer. The carrier wafer includes a plurality of holes extending through a substrate. The carrier wafer is adhered to a surface of the heat-generating device, and the resulting package is placed in the dielectric liquid. The actuator vibrates and increases the rate of liquid flow past the heat-generating device, improving the cooling effect.

### BACKGROUND

Micro-electromechanical systems (MEMS) is a technology that employs miniature mechanical and electro-mechanical elements (e.g., devices or structures) on a wafer substrate. Devices or structures that can be used in MEMS include sensors, actuators, and other structures. MEMS devices may be used in a wide range of applications.

MEMS structures can be made using photolithographic patterning processes that use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic perspective view of a package formed from a heat-generating device with a MEMS cooling device attached thereto, in accordance with some embodiments of the present disclosure.

FIG. 1B is a plan view of a MEMS actuator through line B-B of FIG. 1A.

FIG. 1C is a cross-sectional view through a portion of a first embodiment of the MEMS cooling device as indicated in FIG. 1B.

FIG. 1D is a magnified plan view of an arm array of the MEMS actuator.

FIG. 1E is a cross-sectional view through a portion of a second embodiment of the MEMS cooling device as indicated in FIG. 1B.

FIG. 1F is an X-axis view of the perimeter region of the carrier wafer through line F-F of FIG. 1E. Three openings are illustrated.

FIG. 2 is a plan view of an adhesive layer and the heat-generating device through line C-C of FIG. 1A.

FIGS. 3A-3D are plan views of different embodiments of a carrier wafer of the MEMS cooling device through line D-D of FIG. 1A.

FIG. 4 is a flow chart illustrating a first method for making a carrier wafer, in accordance with some embodiments.

FIG. 5A is a plan view of the substrate with an initial mask that exposes a perimeter region when openings on the front side of the carrier wafer are desired. FIG. 5B is a Y-axis cross-sectional view through line B-B of FIG. 5A. FIG. 5C is a Y-axis cross-sectional view through line C-C of FIG. 5A.

FIG. 5D is a Y-axis cross-sectional view through line C-C of FIG. 5A after etching.

FIG. 6A is a plan view of the substrate with a first mask that exposes an intermediate region. FIG. 6B is a Y-axis cross-sectional view through line B-B of FIG. 6A.

FIG. 7 is a side cross-sectional view of the substrate after etching to form one or more cavities in the intermediate region.

FIG. 8 is a side cross-sectional view of the substrate with a second mask that exposes parts of the cavities.

FIG. 9 is a side cross-sectional view of the substrate after etching to form holes that extend to the back side of the carrier wafer.

FIG. 10 is a side cross-sectional view of another embodiment of a MEMS cooling device, in accordance with some embodiments of the present disclosure. Here, the central region of the carrier wafer includes a plurality of steps extending downwards towards the intermediate region.

FIG. 11A is a plan view of a first example embodiment of the carrier wafer having a plurality of steps.

FIG. 11B is a plan view of a second example embodiment of the carrier wafer having a plurality of steps.

FIG. 12 is a flow chart illustrating a second method for making a carrier wafer, in accordance with some embodiments. The central region of the carrier wafer includes a plurality of steps.

FIG. 13 is a side cross-sectional view of the substrate after applying a first mask and forming a first step.

FIG. 14 is a side cross-sectional view of the substrate after applying a second mask and forming a first plateau.

FIG. 15 is a side cross-sectional view of the substrate after applying a third mask and forming a second plateau.

FIG. 16 is a side cross-sectional view of the substrate after applying a fourth mask and forming a third plateau.

FIG. 17 is a side cross-sectional view of the substrate after applying a fifth mask and forming trenches/floors between the plateaus.

FIG. 18 is a side cross-sectional view of the substrate after applying an optional sixth mask and forming holes in the intermediate region.

FIG. 19 is a magnified side cross-sectional view of the central region of the carrier wafer, showing more detail relating to the steps and trenches.

FIG. 20 is a flow chart illustrating another method for making a carrier wafer, in accordance with some embodiments. This is an alternate method for forming the central region with a plurality of steps.

FIG. 21 is a side cross-sectional view of the substrate after applying a first mask and forming a trench that includes a sloped sidewall in the central region and a cavity in the intermediate region.

FIG. 22 is a side cross-sectional view of the substrate after applying a second mask. The second mask covers the intermediate region and exposes trenches in the central region.

FIG. 23 is a side cross-sectional view of the substrate after etching to form trenches/floors between steps in the central region.

FIG. 24 is a side cross-sectional view of the substrate after removing the second mask.

FIG. 25 is a side cross-sectional view of the substrate after applying an optional third mask. The third mask covers the central region and exposes hole regions in the intermediate region.

FIG. 26 is a side cross-sectional view of the substrate after etching to form the holes and removing the third mask.

FIG. 27 is a flow chart illustrating a method for making or assembling a MEMS cooling device with a carrier wafer, and subsequently using the MEMS cooling device on a heat-generating device, in accordance with some embodiments.

FIG. 28 is a side cross-sectional view of an interposer, showing various locations where the MEMS cooling device could be attached.

FIG. 29A is a perspective view of a dual-phase immersion cooling system.

FIG. 29B is a side view of the dual-phase immersion cooling system.

FIG. 30 is a side view of a single-phase immersion cooling system.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The disclosure refers to “length” and “width”. These terms should not be construed as implying the length must have a greater value than the width, and are not necessarily used consistently herein with respect to the axis in which they are measured.

The present disclosure relates to structures which are made up of different layers. When the terms “on” or “upon” or “over” are used with reference to two different layers (including the substrate), they indicate merely that one layer is on or upon or over the other layer. These terms do not require the two layers to directly contact each other, and permit other layers to be between the two layers. For example all layers of the structure can be considered to be “on” or “over” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to micro-electromechanical system (MEMS) devices that can be used in liquid cooling applications. Such MEMS cooling devices can include an actuator and a carrier wafer which are bonded together. The MEMS actuator can convert energy, such as heat energy or electrical signals or liquid pressure differential, into physical motion or mechanical force. The carrier wafer is bonded to the actuator, and includes one or more holes through which liquid can flow. Vibration of the actuator causes liquid flow. When used in the presence of a heat-generating device, the liquid flow causes cooling liquid to move more quickly past the heat-generating device for higher heat transfer.

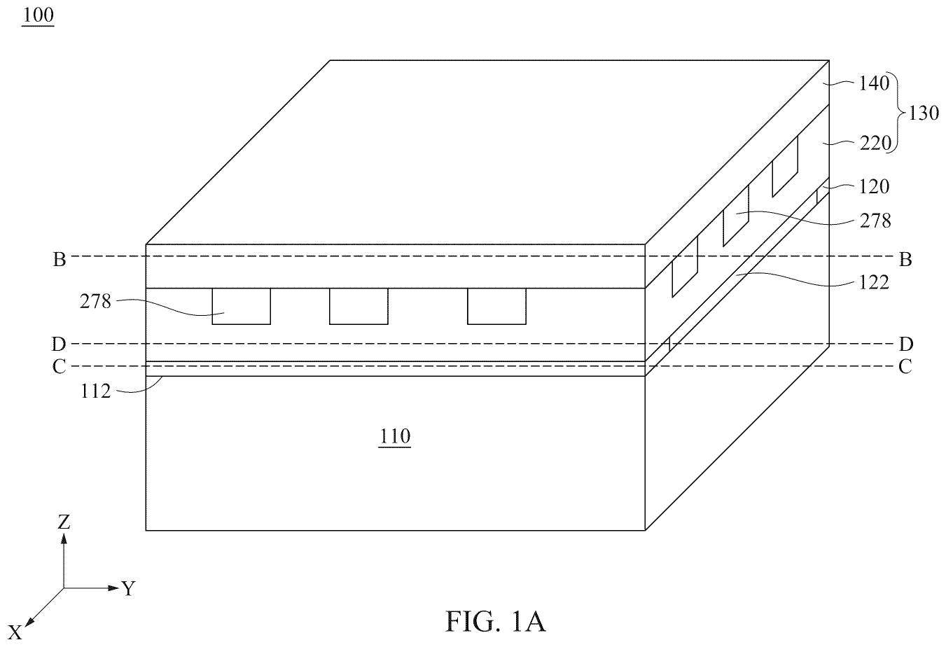

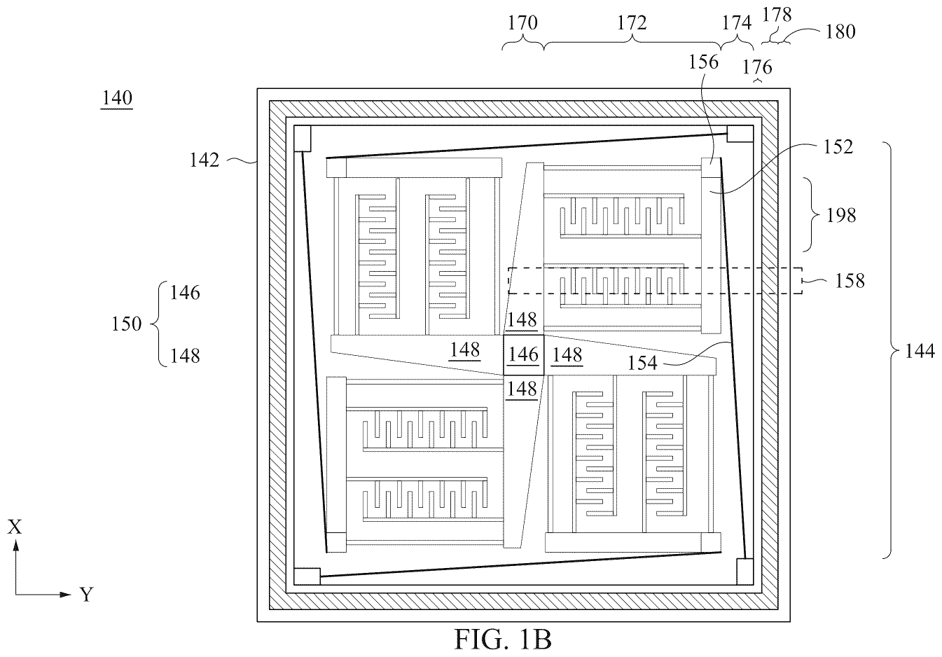

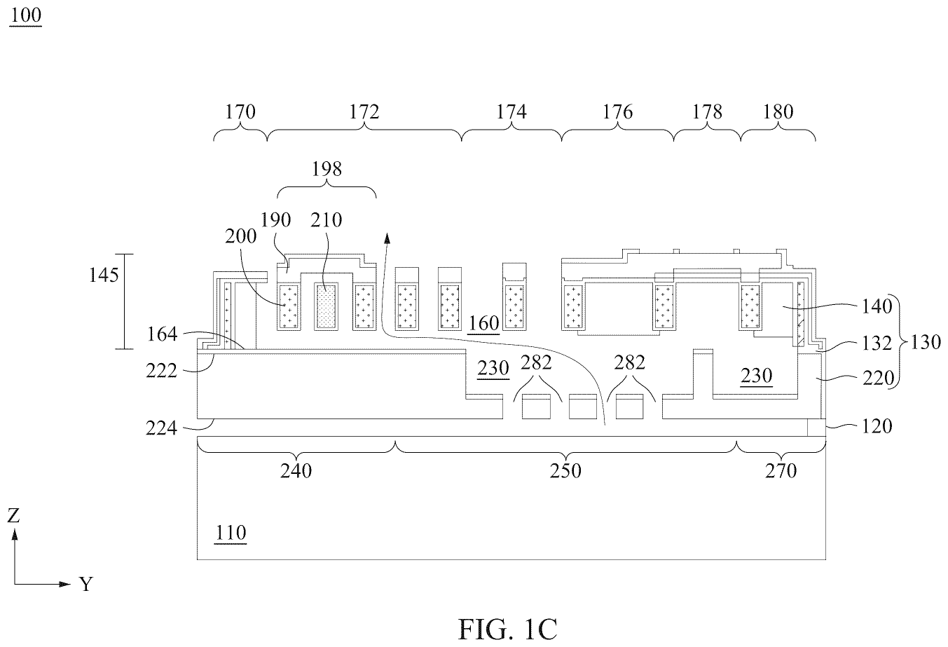

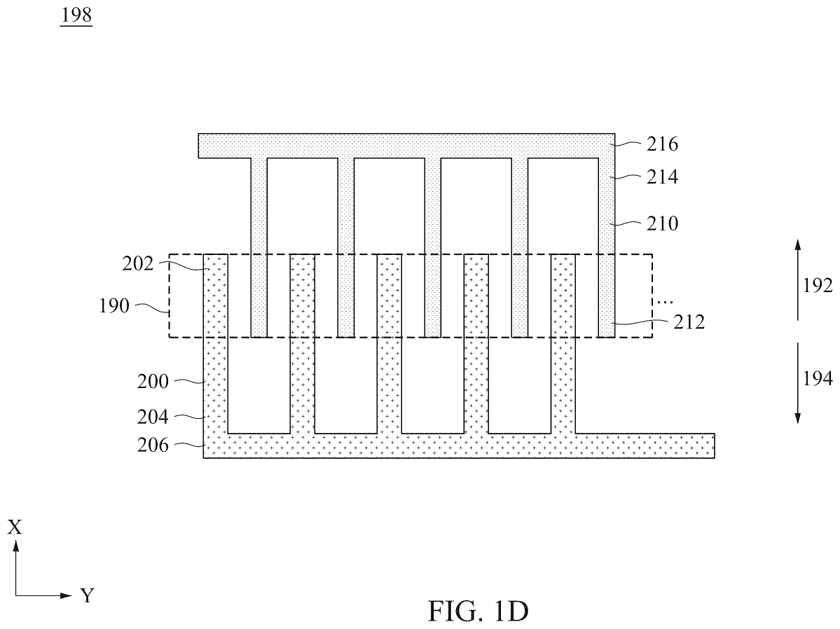

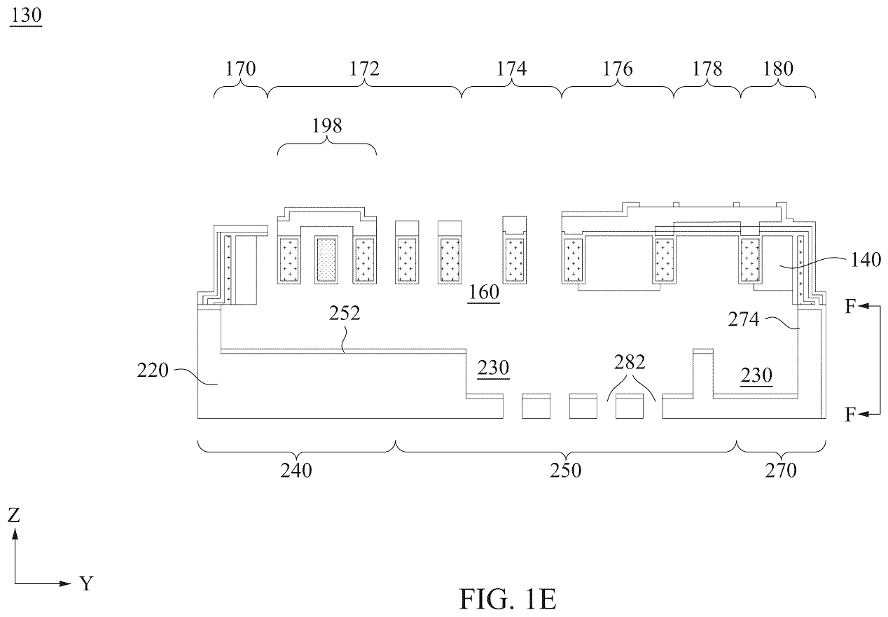

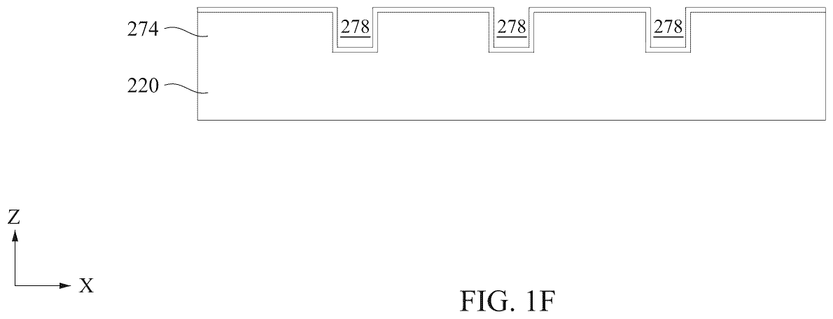

FIG. 1A is a schematic perspective view of a package 100 that includes a heat-generating device 110 with a MEMS cooling device 130 attached thereto, in accordance with some embodiments of the present disclosure. The MEMS cooling device 130 includes a MEMS actuator 140 bonded to a carrier wafer 220. The carrier wafer 220 is adhered to a surface 112 of the heat-generating device 110 through an adhesive layer 120. The adhesive layer is discontinuous, or in other words includes spaces 122 so that liquid can flow between the surface 112 of the heat-generating device 110 and the carrier wafer 220. As illustrated here, lateral openings 278 are also present in one or more sides of the carrier wafer 220.

FIG. 1B is a plan view of the MEMS actuator 140 through line B-B of FIG. 1A. FIG. 1C is a cross-sectional view through a portion of a first embodiment of the package as indicated by dashed box 158 in FIG. 1B. FIG. 1D is a magnified plan view of an arm array 198 of the MEMS actuator.

Referring to FIGS. 1B-1D, the MEMS cooling device 130 includes a MEMS actuator 140 and a carrier wafer 220, which are bonded together through a bonding layer 132. In FIG. 1B, the illustrated actuator 140 includes a four-sided frame 142 which surrounds and is spaced apart from a vibration component 144. The vibration component 144 includes an anchor 146 located at the center. As illustrated here, four anchor arms 148 extend from the anchor, and together they can be considered an anchor structure 150.

In FIG. 1C, the actuator 140 has multiple sections in the horizontal direction, which are labeled as an anchor arm section 170, a driving comb section 172, a hinge section 174, an inner frame section 176, a spring section 178, and an outer frame section 180. The anchor arm section 170 is part of the anchor arm 148. The inner frame section 176, spring section 178, and outer frame section 180 make up part of the frame 142 of the actuator. Micromechanical arm arrays 198 are located in the driving comb section 172. These illustrated sections together make up a quadrant of a MEMS actuator (the other three quadrants having the same structure, suitably rotated).

The anchor arm section 170 provides structural integrity and aids in supporting the driving comb section. The hinge section 174 allows for pivotal movement, or allows for the controlled rotation of other components relative to the driving comb section. The inner frame section 176 provides structural support and stability. The spring section 178 provides some elasticity to maintain the desired positioning and movement of the components, and also provides a restoring force to bring the components back to their original position after actuation. The outer frame section 180 generally provides structural integrity, protecting the internal components from some external and environmental forces.

An empty cavity 160 is present within the actuator 140. The micromechanical arm array 198 is disposed within the cavity and can move freely within the cavity. The cavity also extends continuously below the hinge section 174, the inner frame section 176, and the spring section 178. Two smaller empty cavities 230 are also present within the carrier wafer 220, which are generally located below the hinge section 174, the inner frame section 176, and the spring section 178. The cavity 160 in the actuator 140 is connected to the two smaller cavities 230 in the carrier wafer 220. Generally, the actuator 140 has a relatively lower thickness 145 (for example in the range of about 200μm) which results in the actuator being very flexible.

Referring more specifically now to FIG. 1C and FIG. 1D, the micromechanical arm array 198 in the actuator contains two separate arrays of fingers, an array of first fingers 200 and an array of second fingers 210, which may be made from an electrically conductive material or a piezoelectric material. A metal cap 190 (shown as dashed box in FIG. 1D) is present above each array of fingers 200, 210.

The first fingers 200 extend in a first direction 192 and are joined to a first arm 206. The proximal ends 204 of the first fingers are joined to the first arm 206, and the distal ends 202 extend away from the first arm in a first direction 192. The second fingers 210 extend in a second direction 194 opposite the first direction and are joined to a second arm 216. The proximal ends 214 of the second fingers are joined to the second arm 216, and the distal ends 212 extend away from the second arm in the second direction 194. The arms are made from the same material as their fingers. The fingers 200, 210, extend in a first horizontal direction (i.e. X-axis, or longitudinal direction). The two arms 206, 216 extend in a second horizontal direction (i.e. Y-axis, or lateral direction). The other ends of the two arms are connected to the anchor arm section 170 and the outer frame section 180. Also illustrated is a metal cap 190 extending over both sets of fingers 200, 210, although only contacting one set of fingers.

The first fingers 200 are spaced apart laterally from each other. Similarly, the second fingers 210 are spaced apart laterally from each other. The first fingers 200 are laterally offset from the second fingers 210. In this plan view, the offset is reflected in the distal ends 202, 212 of the fingers 200, 210 being interposed or interlaced with each other. The fingers can vibrate in the X-axis, Y-axis, and Z-axis relative to each other

Referring back to FIG. 1B, the vibration component 144 can be described as having four quadrants, each quadrant being located between two anchor arms. Within each quadrant, an anchor arm 148 supports one or more micromechanical arm arrays 198 within a driving comb section 172 as previously described. As illustrated here, the driving comb section includes two micromechanical arm arrays, but any number of such arrays may be present. In particular embodiments, the driving comb section may contain from one to ten micromechanical arm arrays. The length of the driving comb section opposite the anchor arm 148 can serve as a support 152. A hinge 154 or cantilever traverses an open space to join the support 152 to a non-adjacent corner of the frame 142. Also located on each support is a separate mount point 156.

Referring now to the carrier wafer 220 as illustrated in FIG. 1C, the carrier wafer 220 includes a central region 240, an intermediate region 250, and a perimeter region 270. The intermediate region is located between the central region and the perimeter region. Generally, the central region 240 of the carrier wafer is located below the anchor arm section 170 and some portion of the driving comb section 172. The intermediate region 250 of the carrier wafer is generally located below some portion of the driving comb section 172 and below the hinge section 174, the inner frame section 176, and some portion of the spring section 178. The perimeter region is generally located below the outer frame section 180 and perhaps some portion of the spring section 178. One or more cavities 230 are present extending from a first or front side 222 of the carrier wafer down into the substrate 221. Here, the cavities 230 are separated by a sidewall 232, and are present in the intermediate region and may also extend into the perimeter region. Finally, one or more holes 282 extend through the substrate to a second or back side 224 of the substrate. Here, a plurality of holes 282 are illustrated and are located within one cavity 230, although they may be present in any or all of the cavities. As a result, a fluid passageway 290 extends entirely through the carrier wafer 220 and through the MEMS actuator 140.

FIG. 1E is a cross-sectional view through a portion of a second embodiment of the MEMS cooling device 130 as indicated in FIG. 1B. in this embodiment, the carrier wafer 220 includes an intermediate surface 252 in the intermediate region 250 which can also extend into the central region 240. The perimeter region 270 includes a sidewall 274. As seen in the X-axis view of FIG. 1F, the sidewall 274 may include one or more lateral openings 278 (three are shown here, see also FIG. 1A). These openings also permit liquid to flow into the open volume within the MEMS cooling device, which can desirably increase turbulence.

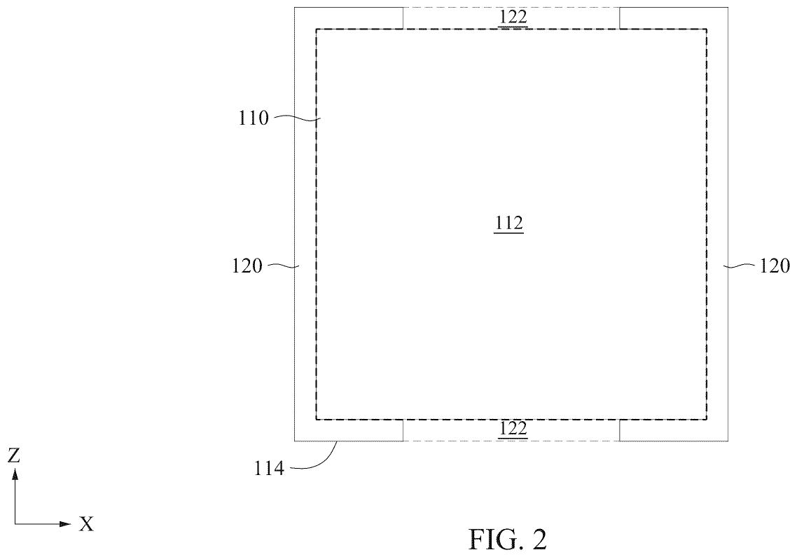

FIG. 2 is a plan view of an adhesive layer and the heat-generating device through line C-C of FIG. 1A. As illustrated here, the adhesive layer 120 is applied along a perimeter 114 of the surface 112 of the heat-generating device 110. In addition, the adhesive layer is discontinuous. Put another way, spaces 122 are left so that cooling liquid can flow into an empty volume between the surface 112 of the heat-generating device and the second side of the carrier wafer.

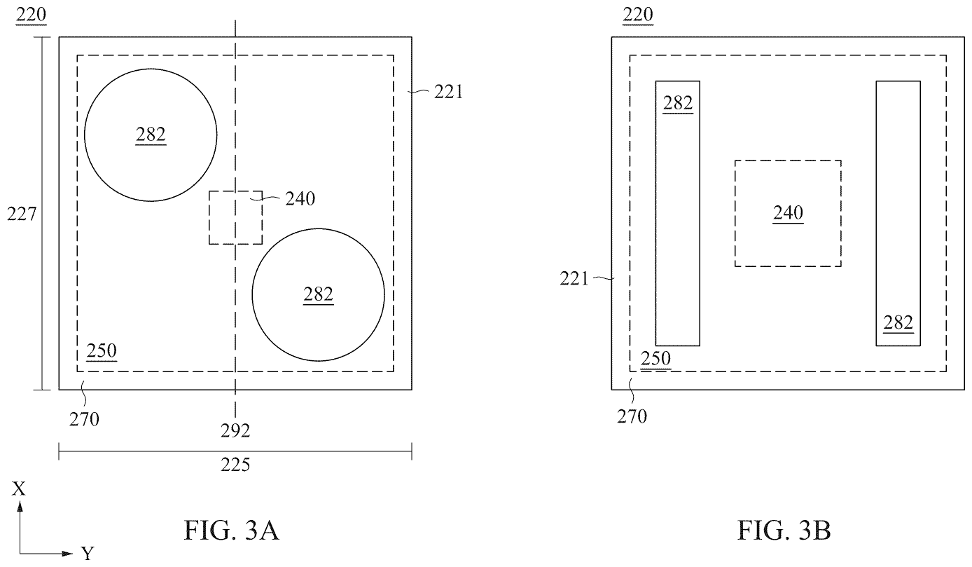

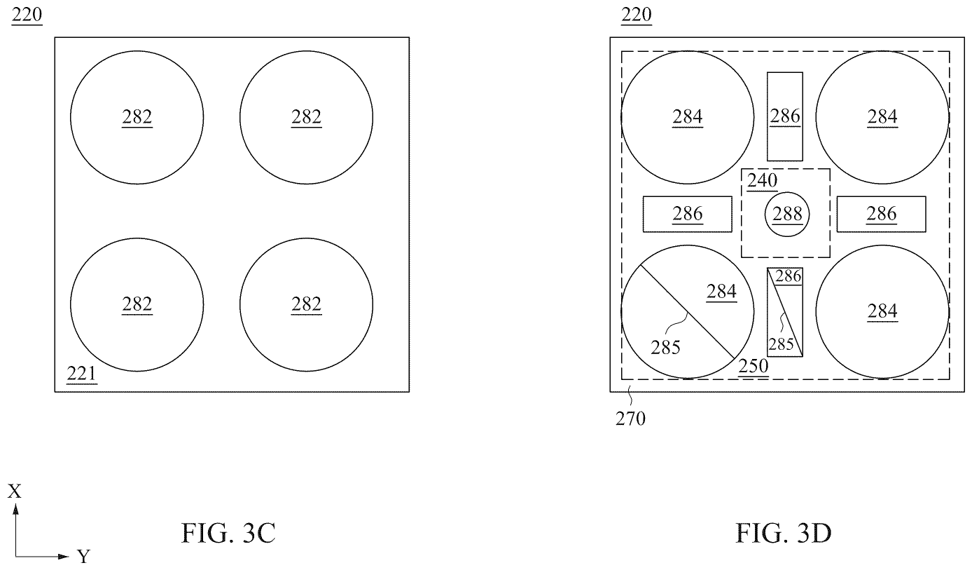

FIGS. 3A-3D are plan views of different embodiments of a carrier wafer 220 of the MEMS cooling device through line D-D of FIG. 1A. In these views, the entire carrier wafer is shown, not just the portion in the dashed box 158 of FIG. 1B. As mentioned above when discussing FIG. 1C, a plurality of holes 282 are present through the carrier wafer substrate 221. In other words, in some embodiments, two or more holes 282, or at least two holes 282, are present through the carrier wafer.

In particular embodiments, the holes are located on opposite sides of the carrier wafer. Put another way, if an imaginary line is drawn through the center of the carrier wafer, at least one hole would be entirely on one side of the imaginary line, and at least one hole would be entirely on the other side of the imaginary line. This is illustrated in FIG. 3A, which has two holes 282 and imaginary line 292 is included. In this figure, the holes are circular. The central region 240, the intermediate region 250, and the perimeter region 270 are also indicated. These three regions do not have a fixed size, and are somewhat arbitrary labels that may depend on the structures located within them. In the embodiment of FIG. 3B, two holes 282 are illustrated that have a rectangular shape. The central region 240 is also larger than that in FIG. 3A.

FIG. 3A also indicates the length 225 and width 227 of the carrier wafer. In particular embodiments, the length 225 is about 30 μm or greater. Similarly, the width 227 is about 30 μm or greater. It is contemplated that the carrier wafer could have maximum dimensions such that only one carrier wafer can be fabricated from a 450-mm wafer, or roughly 318 mm×318 mm. Other ranges and values are also within the scope of the present disclosure.

The embodiment illustrated in FIG. 3C has four holes, one located in each quadrant. The embodiment illustrated in FIG. 3D has three types of holes 284, 286, 288. Holes 284, 288 are illustrated with a circular shape, and holes 286 are illustrated with a rectangular shape. It is noted that a hole 288 is located in the central region 240, which is also permitted. In such an embodiment, the thickness of the central region might be the same as that of the intermediate region. Generally, each hole may be of any suitable shape or surface area (when viewed in a plan view), so long as the hole extends through the entire substrate. In particular embodiments, a first hole 284 and a second hole 286 in the plurality of holes have different surface areas or shapes. This can enhance the intensity of liquid flow.

In particular embodiments, each hole may have a diameter 285 of about 2 micrometers (μm) to about 10 μm. With respect to non-circular holes, the term “diameter” refers to the longest length through which liquid may pass through the hole. For example, the diameter of the rectangular hole 286 is its diagonal between opposite corners.

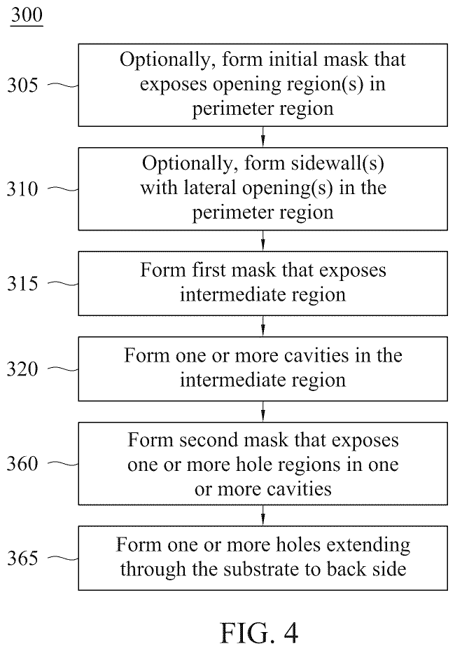

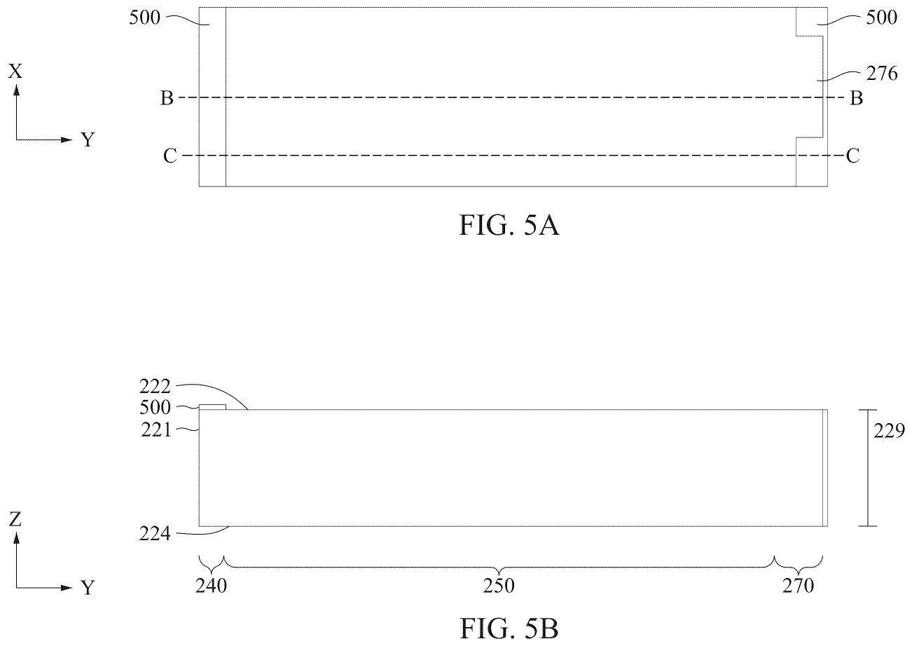

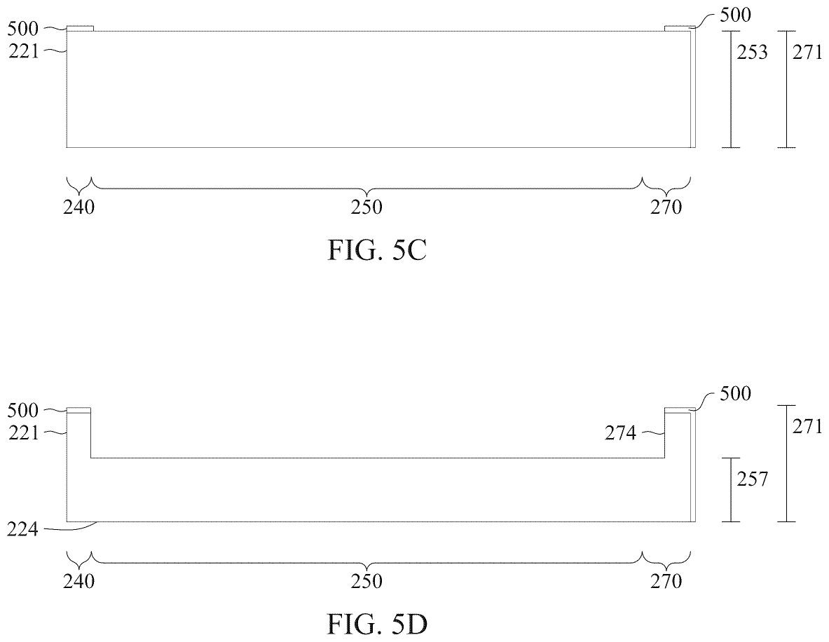

FIG. 4 is a flow chart illustrating a first method 300 for making a carrier wafer through which liquid can flow, in accordance with some embodiments. Some steps of the method are also illustrated in FIGS. 5A-9. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 158 of FIG. 1B and in FIG. 1C. Other structures may also be concurrently formed. It is noted that not all steps described in the flow chart are required, and not all method steps are described in the flow chart.

Referring first to FIG. 5A and FIG. 5B, the method begins with a substrate 221 The base substrate may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate 221 has a first side/front side/upper surface 222 and a second side/back side/lower surface 224, and has an initial thickness 229 between these two surfaces.

If it is desired to form openings 278 as illustrated in the embodiment of FIG. 1E and FIG. 1F, then as indicated in optional step 305 of FIG. 4 and as illustrated in FIGS. 5A-5C, an initial mask 500 is formed upon the first side 222 of the substrate. One or more opening regions 276 are exposed in the perimeter region 270 of the substrate 221. The intermediate region 250 is also exposed. As illustrated here, the central region 240 is not exposed, but this is not required (i.e. some portions or all of the central region can be exposed too). The absence of the initial mask in the opening region 276 of the perimeter region is seen in FIG. 5B. Also indicated in FIG. 5C are an initial thickness 253 of the intermediate region 250 and an initial thickness 271 of the perimeter region 270, which are currently equal. The presence of the initial mask 500 in the rest of the perimeter region 270 is seen in FIG. 5C.

Then, as indicated in optional step 310 of FIG. 4 and as illustrated in FIG. 5D, a sidewall 274 with one or more openings (not visible) is formed in the perimeter region 270. An intermediate thickness 257 of the intermediate region is indicated. The intermediate thickness 257 of the intermediate region is less than the initial thickness 271 of the perimeter region (measured relative to the second side 224 of the substrate). FIG. 1F shows an X-axis view where three openings 278 are formed. This may be done by etching. The initial mask is then removed.

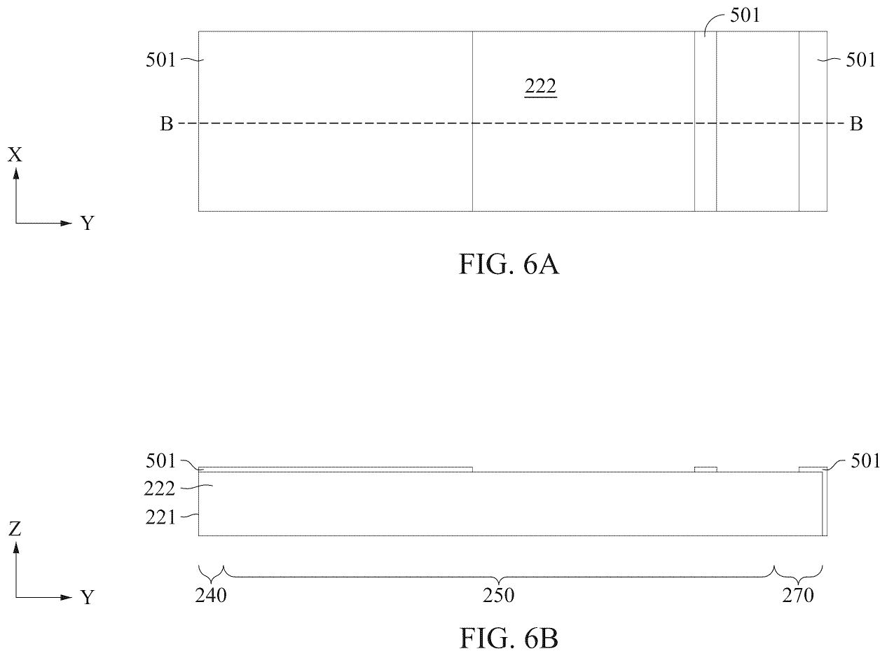

Alternatively, as indicated in step 315 of FIG. 4 and as illustrated in FIG. 6A and FIG. 6B, a first mask 501 is formed upon the first side 222 of the substrate. A portion of the intermediate region 250 is exposed. As illustrated here, the central region 240 is not exposed, but this is not required (i.e. some portions or all of the central region can be exposed too). Similarly, a portion of the perimeter region 270 is not exposed.

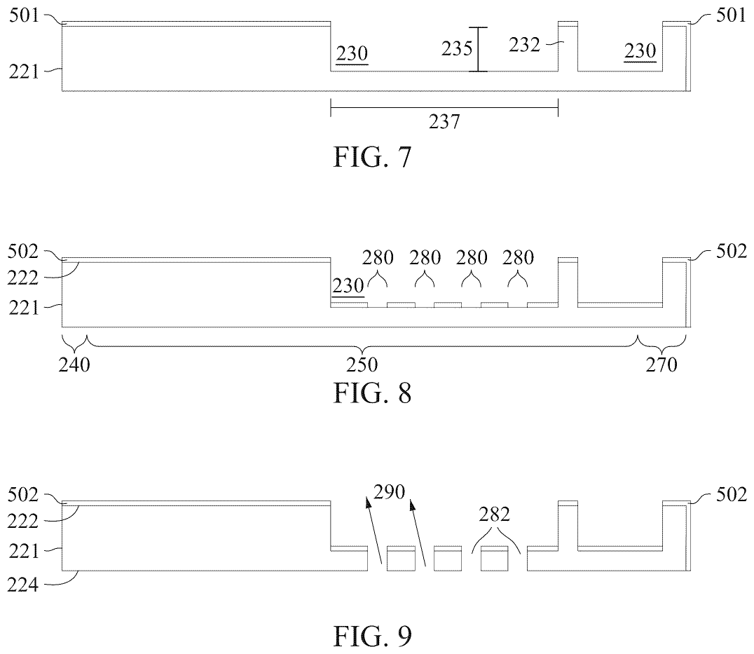

Continuing, as indicated in step 320 of FIG. 4 and as illustrated in FIG. 7, one or more cavities 230 are formed in the intermediate region 250. This may be done by etching through the first mask 501. The resulting structure is shown in FIG. 7, which illustrates two cavities 230 separated from each other by a sidewall 232.

In particular embodiments, at least one cavity 230 has a depth 235 of about 10 μm or greater. At least one cavity has a length 237 of about 20 μm or greater. Other ranges and values are also within the scope of the present disclosure.

Subsequently, as indicated in step 360 of FIG. 4 and as illustrated in FIG. 8, a second mask 502 is formed upon the first side 222 of the substrate. One or more hole regions 280 are exposed in the intermediate region 250. A plurality of hole regions is illustrated here. As shown here, the hole regions are illustrated as being in one cavity 230, but they may be present in other cavities as well.

Finally, as indicated in step 365 of FIG. 4 and as illustrated in FIG. 9, one or more holes 282 are formed that extend entirely through the substrate 221. Put another way, a fluid passageway 290 thus extends entirely through the carrier wafer 220 from the first side 222 to the second side 224. Here, a plurality of holes is illustrated. This may be done by etching through the second mask 502. The resulting structure corresponds to the carrier wafer illustrated in FIG. 1C. It is noted that if the second mask 502 is a hard mask instead of photoresist, then the second mask does not need to be removed before the carrier wafer is attached to the MEMS actuator. If the optional steps 305, 310 are performed, the resulting structure would correspond to the carrier wafer illustrated in FIG. 1E.

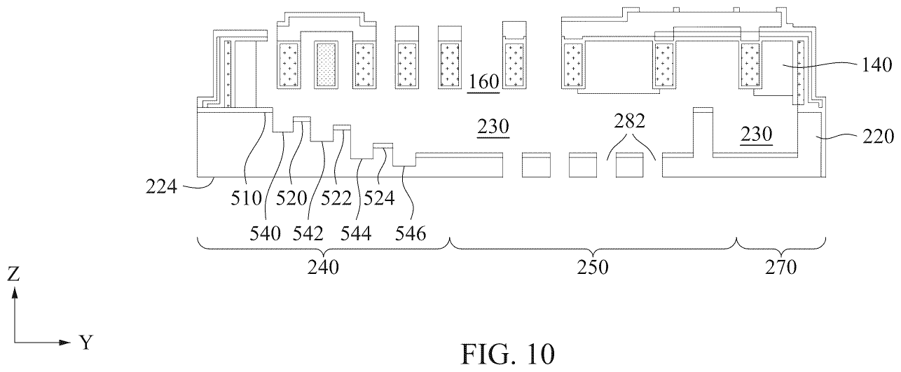

FIG. 10 is a side cross-sectional view of another embodiment of a MEMS cooling device which can be attached to a heat-generating device, in accordance with some embodiments of the present disclosure. Here, the central region 240 of the carrier wafer 220 includes a plurality of steps 510 extending downwards towards the intermediate region 250. In this illustration, four steps 510, 520, 522, 524 are present. In some particular embodiments, there are 1 to 4 steps, although other values are within the scope of the present disclosure. The top step 510 is bonded to the MEMS actuator 140. The other three steps 520, 522, 524 are located between trenches 540, 542, 544, 546. Two cavities 230 are illustrated, one of which may be considered as extending into the central region 240 as well. Four holes 282 that extend to the second side 224 of the substrate are also illustrated. The presence of the steps may aid in changing the direction of liquid flow and/or increasing the rate of liquid flow through the carrier wafer. This can also create turbulence in the liquid flow.

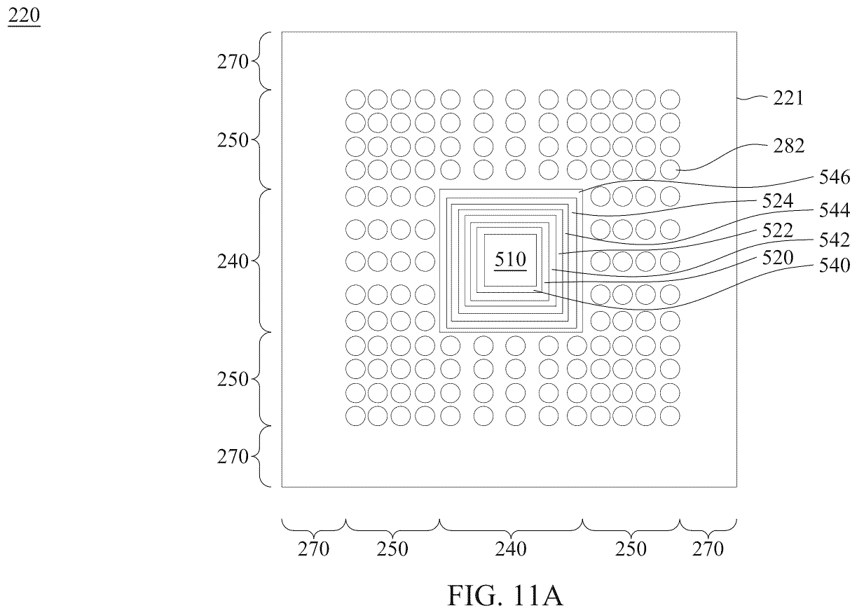

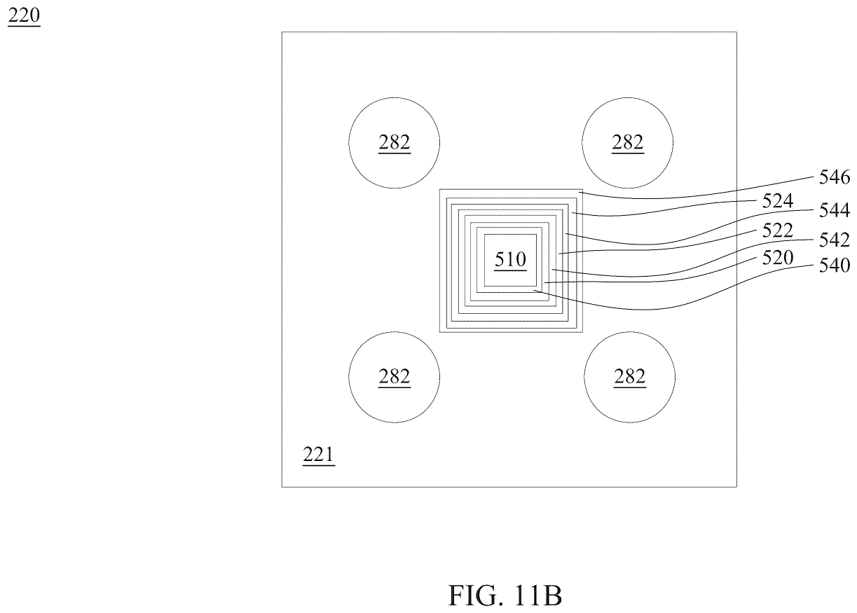

FIG. 11A is a plan view of the entire carrier wafer 220 of FIG. 10 (i.e. not corresponding to the partial view of FIG. 10). The four steps 510, 520, 522, 524 are seen as having a rectangular shape, along with the trenches 540, 542, 544, 546. This particular embodiment is illustrated with 84 holes 282, and reflects the variety of designs that can be made in the carrier wafer. FIG. 11B is a plan view of another embodiment of the carrier wafer 220. Here, the steps 510 are present, along with four relatively large holes 282 in the carrier wafer 220.

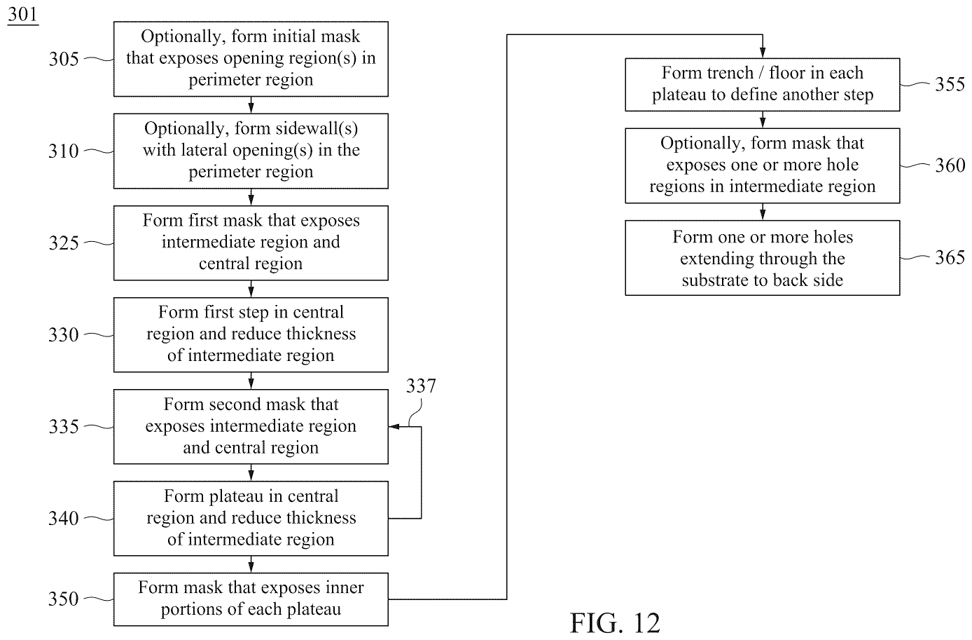

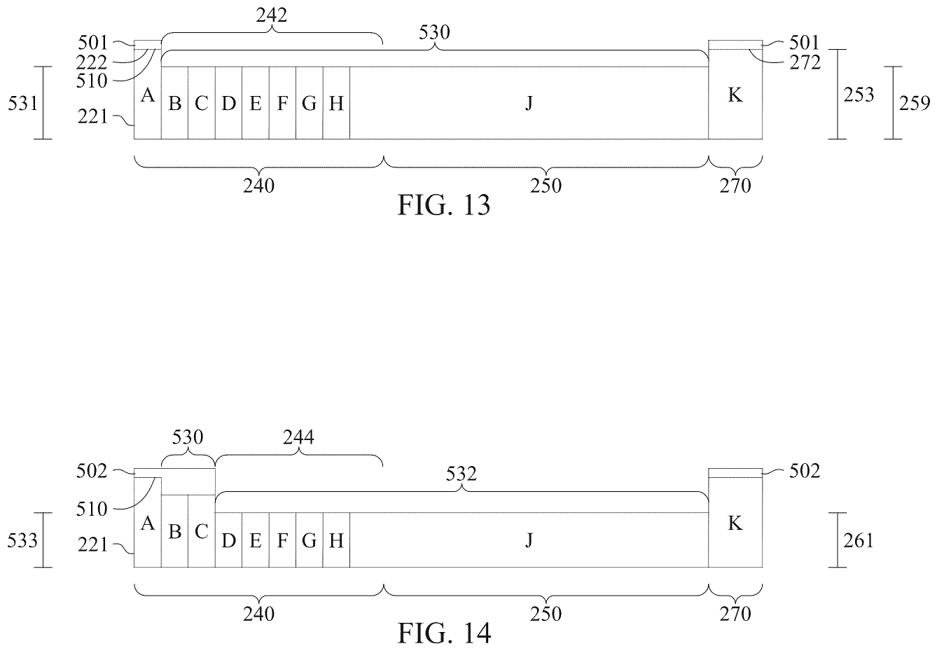

FIG. 12 is a flow chart illustrating a second method 301 for making a carrier wafer through which liquid can flow, in accordance with some embodiments. Some steps of the method are also illustrated in FIGS. 13-18. In particular, the carrier wafer is patterned to form a plurality of steps in the central region. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 158 of FIG. 1B and in FIG. 10. Other structures may also be concurrently formed. It is noted that not all steps described in the flow chart are required, and not all method steps are described in the flow chart.

Initially, if it is desired to form openings 278 as illustrated in the embodiment of FIG. 1E and FIG. 1F, then as indicated in optional step 305 of FIG. 12, an initial mask 500 is formed upon the first side 222 of the substrate. Then, as indicated in optional step 310 of FIG. 4, a sidewall 274 with one or more openings 278 is formed in the perimeter region 270. These steps were previously illustrated in FIGS. 5A-5D, and are not repeated here.

As indicated in step 325 of FIG. 12 and as illustrated in FIG. 13, a first mask 501 is formed over the first side 222 of the substrate 221. The intermediate region 250 and a first portion 242 of the central region 240 is exposed. The perimeter region 270 is covered. For reference purposes, the substrate is labeled as having columns A, B, C, D, E, F, G, H, J, and K. Columns A-H are in the central region, column J is in the intermediate region, and column K is in the perimeter region.

Then, as indicated in step 330 of FIG. 12, a top step or first step 510 is formed in the central region 240, along with a first plateau 530. This may be done by etching. The first plateau 530 is located below the first step 510, and is adjacent to the first step 510. Here, column A corresponds to the top step, and columns B through H together form the first plateau. The thickness of the intermediate region 250 has been reduced from an initial thickness 253 to a first intermediate thickness 259. The height 531 of the first plateau 530 corresponds to the first intermediate thickness 259 of the intermediate region. In particular embodiments, the top step 510 is level with the upper surface 272 of the perimeter region 270.

Next, as indicated in step 335 of FIG. 12 and as illustrated in FIG. 14, a second mask 502 is formed over the first side of the substrate 221. The intermediate region 250 and a second portion 244 of the central region 240 is exposed. The second portion surrounds the first portion 242 (in a plan view). Then, as indicated in step 340 of FIG. 12, a second plateau 532 is formed in the central region. This may be done by etching. The second plateau 532 is located below the first plateau 530, and is adjacent to the first plateau 530. Here, the first plateau is now formed by columns B and C, and columns D through J together form the second plateau. The thickness of the intermediate region 250 has been reduced from the first intermediate thickness 259 to a second intermediate thickness 261. The height 533 of the second plateau 532 corresponds to the second intermediate thickness 261 of the intermediate region. As indicated by step 337 of FIG. 12, steps 335 and 340 may be repeated to create any desired number of plateaus.

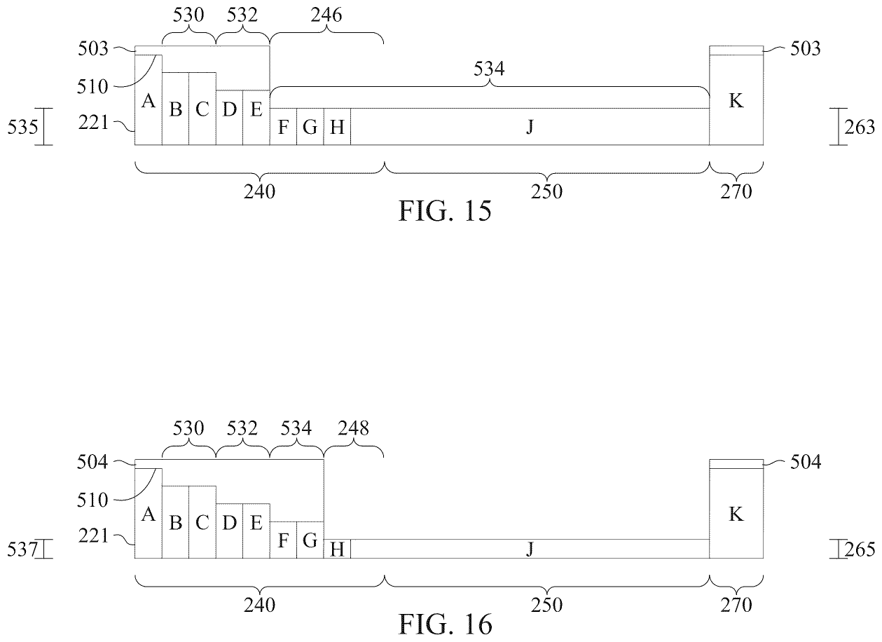

As illustrated in FIG. 15, a third mask 503 is formed over the first side of the substrate 221. The intermediate region 250 and a third portion 246 of the central region 240 is exposed. The third portion 246 surrounds the second portion 244. Then, a third plateau 534 is formed in the central region. This may be done by etching. The third plateau 534 is located below the second plateau 532, and is adjacent to the second plateau 532. Here, the second plateau is now formed by columns D and E, and columns F through J together form the third plateau. The thickness of the intermediate region 250 has been reduced from the second intermediate thickness 261 to a third intermediate thickness 263. The height 535 of the third plateau 534 corresponds to the third intermediate thickness 263 of the intermediate region.

As illustrated in FIG. 16, a fourth mask 504 is formed over the first side of the substrate 221. The intermediate region 250 and a fourth portion 248 of the central region 240 is exposed. Columns H corresponds to the fourth portion. The fourth portion 248 surrounds the third portion 246. After etching. the thickness of the intermediate region 250 has been reduced from the third intermediate thickness 263 to a final thickness 265. The height 537 of column H in the central region corresponds to the final thickness 265 of the intermediate region.

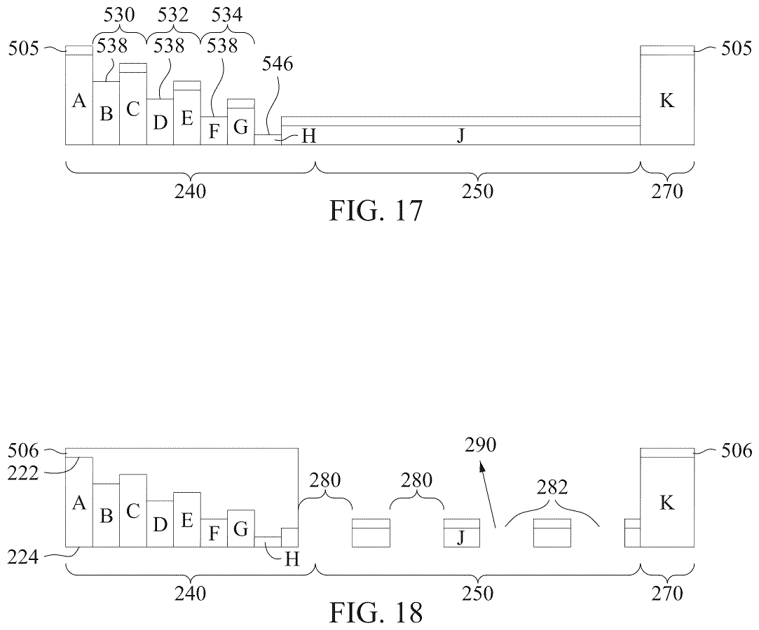

Then, as indicated in step 350 of FIG. 12 and as illustrated in FIG. 17, a fifth mask 505 is formed over the first side of the substrate 221. The fifth mask covers the intermediate region 250 and the perimeter region 270. In the central region 240, the mask exposes an inner portion 538 of each plateau, and covers the outer portion of each plateau. In this illustrated embodiment, the mask also exposes column H. Next, as indicated in step 355 of FIG. 12, a trench or floor is formed in each plateau 530, 532, 534. This may be done by etching. Here, the floors corresponds to columns B, D, and F. A trench 546 is also formed in column H, though this is not required. Steps are defined by the outer portions of each plateau. Here, the steps 520, 522, 524 correspond to columns C, E, and G.

Subsequently, as indicated in optional step 360 of FIG. 12 and as illustrated in FIG. 18, a sixth mask 506 is formed upon the first side of the substrate. The sixth mask covers the central region 240 and the perimeter region 270, and exposes one or more hole regions 280 in the intermediate region 250 of column J. Finally, as indicated in step 365 of FIG. 12, one or more holes 282, such as a plurality of holes, are formed in the hole regions that extend entirely through the substrate 221. A fluid passageway 290 thus extends entirely through the carrier wafer 220 from the first side 222 to the second side 224. This may be done by etching through the sixth mask 506. The resulting structure corresponds to the carrier wafer illustrated in FIG. 10. Again, the last mask 506 does not need to be removed if it is a hard mask. In this regard, it is noted that the fifth mask 505 could also be patterned to expose hole regions 280 in some embodiments where the final thickness 265 of the intermediate region is less than or equal to the trench depths formed in the central region 240, and so a sixth mask may not be needed.

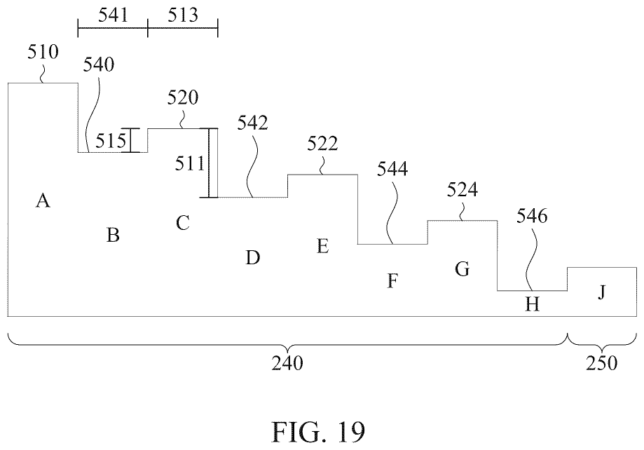

FIG. 19 is a magnified view of the central region 240 and an adjacent portion of the intermediate region 250, and shows more detail. As previously mentioned, there are four steps 510, 520, 522, 524 and four trenches 540, 542, 544, 546. In particular embodiments, each step has a height 511 as measured from the downstream trench of about 2 μm to about 3 μm. In particular embodiments, each step has a cross-sectional length 513 of about 2 μm to about 3 μm. Similarly, in particular embodiments, each trench has a cross-sectional length 541 of about 2 μm to about 3 μm. In particular embodiments, each step has a height 515 as measured from the upstream trench of about 1 μm to about 2 μm. Other ranges and values are also within the scope of the present disclosure.

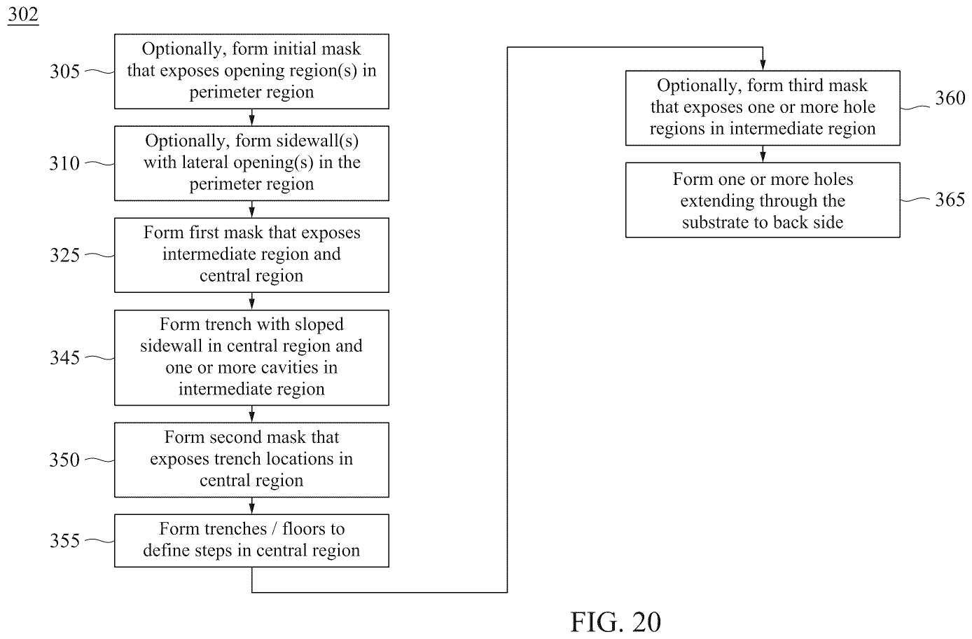

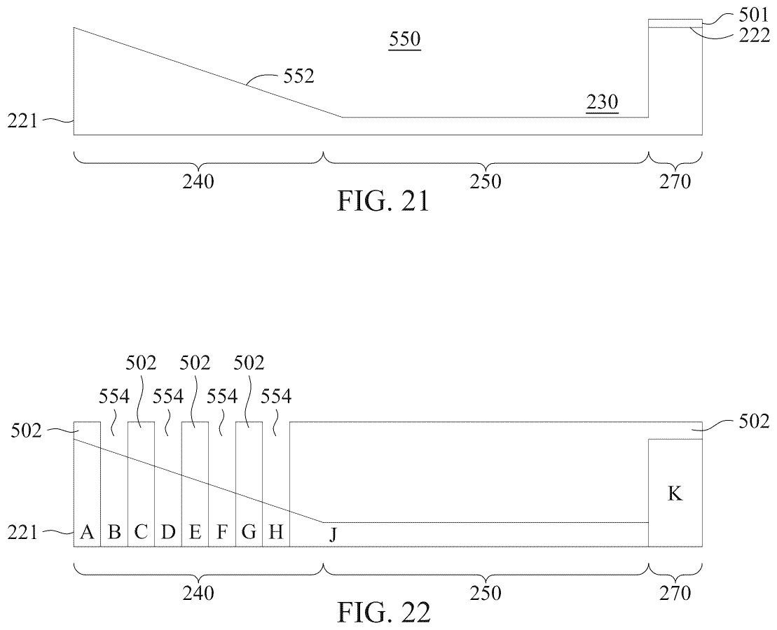

FIG. 20 is a flow chart illustrating another method 302 for making a carrier wafer through which liquid can flow, in accordance with some embodiments. In particular, the carrier wafer includes a plurality of steps in the central region. Some steps of the method are also illustrated in FIGS. 21-26. These figures provide different views for better understanding. While the method steps are discussed below in terms of forming a single carrier wafer, such discussion should also be broadly construed as applying to the concurrent formation of multiple carrier wafers. These figures do not show the formation of the entire carrier wafer, but are illustrated for the portion in the dashed box 158 of FIG. 1B and in FIG. 10. Other structures may also be concurrently formed. It is noted that not all steps described in the flow chart are required, and not all method steps are described in the flow chart.

Initially, if it is desired to form openings 278 as illustrated in the embodiment of FIG. 1E and FIG. 1F, then as indicated in optional step 305 of FIG. 20, an initial mask 501 is formed upon the first side 222 of the substrate. Then, as indicated in optional step 310 of FIG. 20, a sidewall 274 with one or more openings 278 is formed in the perimeter region 270. These steps were previously illustrated in FIGS. 5A-5D, and are not repeated here.

As indicated in step 325 of FIG. 20 and as illustrated in FIG. 21, a first mask 501 is formed over the first side 222 of the substrate 221. The intermediate region 250 and the central region 240 are exposed. The perimeter region 270 is covered. Then, as indicated in step 345 of FIG. 20, a trench 550 is formed that includes a sloped sidewall 552 in the central region 240. The trench extends into the intermediate region 250, and can also be considered a cavity 230 in the intermediate region 250. This may be performed by etching, and more specifically multiple etching steps at different angles to obtain the sloped sidewall. The tapered or sloped sidewall 552 is angled downwards towards the intermediate region 250. The resulting structure is shown in FIG. 21.

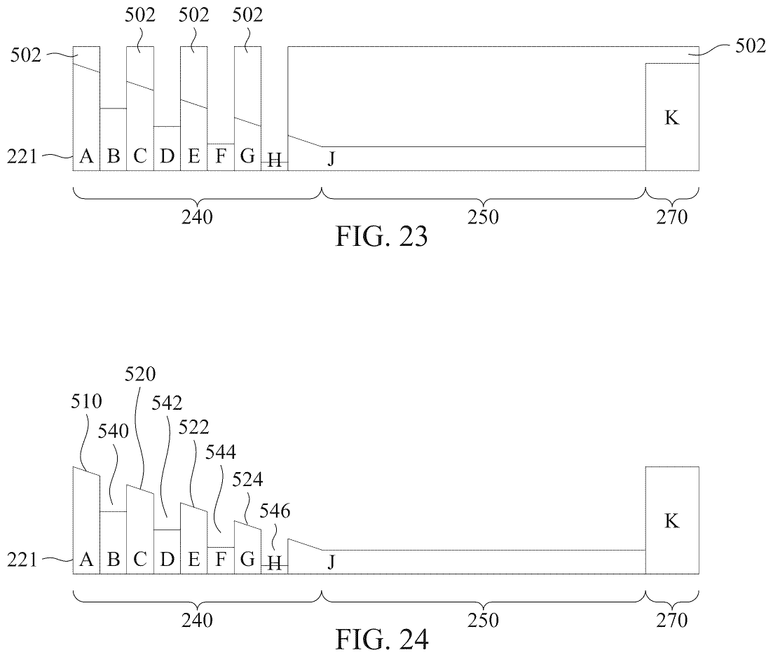

Next, after removing the first mask, as indicated in step 350 of FIG. 20 and as illustrated in FIG. 23, a second mask is formed over the first side of the substrate 221. The second mask covers the intermediate region 250 and the perimeter region 270. In the central region 240, trench regions 554 are exposed. The exposed trench regions correspond to columns B, D, F, and H.

Continuing, as indicated in step 355 of FIG. 20 and as illustrated in FIG. 24, a trench or floor 540, 542, 544, 546 is formed in each trench region. This may be done by etching. Here, the floors corresponds to columns B, D, F, and H. Thus, the steps 510, 520, 522, 524 correspond to columns A, C, E, and G. FIG. 24 illustrates the resulting structure after the second mask is removed.

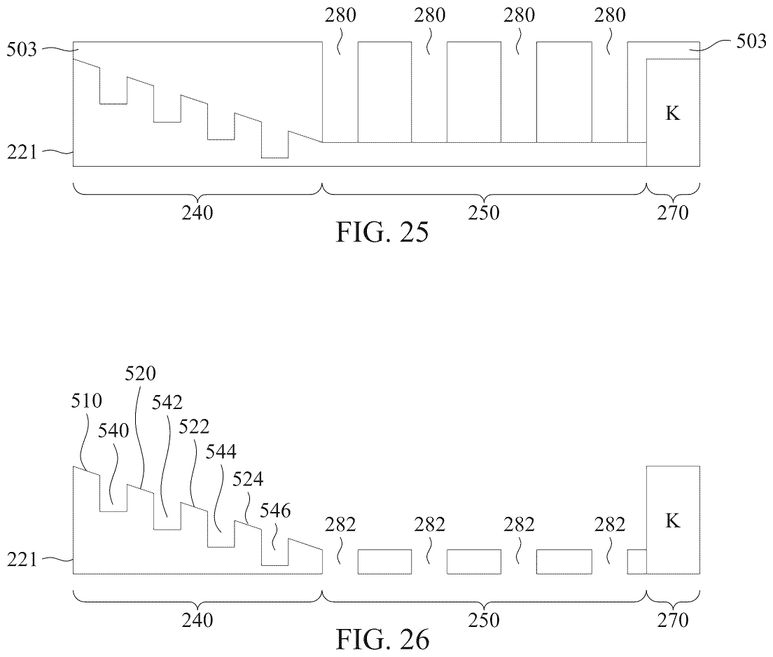

Subsequently, as indicated in optional step 360 of FIG. 20 and as illustrated in FIG. 25, a third mask 503 is formed upon the first side of the substrate. The third mask covers the central region 240 and the perimeter region 270, and exposes one or more hole regions 280 in the intermediate region 250 of column J. Finally, as indicated in step 365 of FIG. 20, one or more holes 282 are formed that extend entirely through the substrate 221. This may be done by etching through the third mask 503. The resulting structure is illustrated in FIG. 26 after the third mask is removed. Again, the last mask 503 does not need to be removed if it is a hard mask. It is also noted that the second mask 502 could also be patterned to expose hole regions 280 in some embodiments where the final thickness 265 of the intermediate region is less than or equal to the trench depths formed in the central region 240, and so a third mask may not be needed.

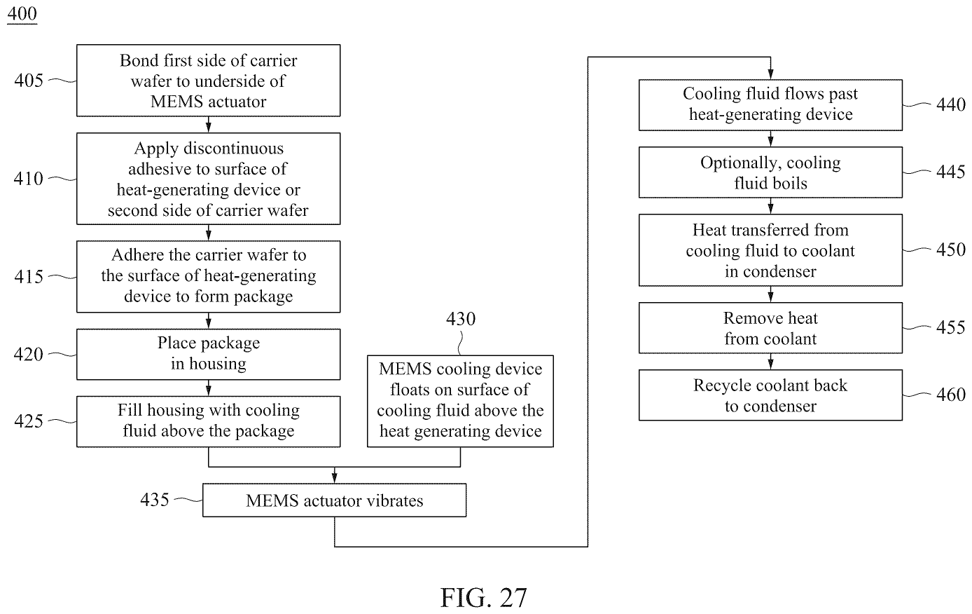

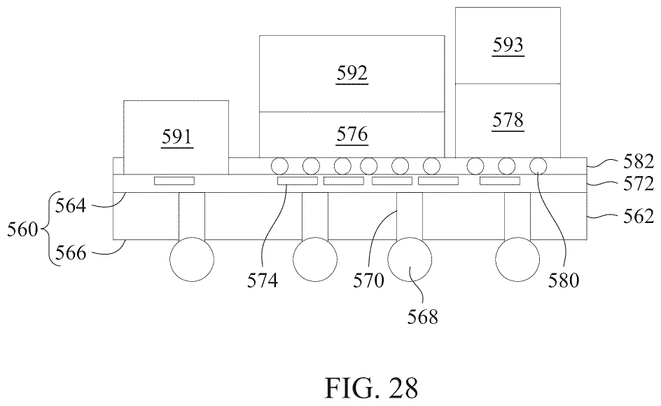

FIG. 27 is a flow chart illustrating a method 400 for making a MEMS cooling device, and for using the MEMS cooling device, in accordance with some embodiments. The method is discussed with reference to FIG. 1C, and also with reference to FIGS. 28-30. Other structures may also be concurrently made or formed. It is noted that not all steps described in the flow chart are required, and not all method steps are described in the flow chart.

Initially, referring to FIG. 1C, the method begins with a MEMS actuator 140 and a carrier wafer 220. As indicated in step 405 of FIG. 27, the first side 222 of the carrier wafer is bonded to the underside 164 of the MEMS actuator through bonding layer 132. This may be done by any suitable technique, such as application of adhesive or other suitable material. The bonding layer may be continuous about the perimeter region 270 or may be discontinuous. The combination of the MEMS actuator 140 and the carrier wafer 220 forms a MEMS cooling device 130.

Then, as indicated in step 410 of FIG. 27 and as illustrated in FIG. 1C, an adhesive 120 is applied to either the second side 224 of the carrier wafer or the surface 112 of the heat-generating device 110. Next, as indicated in step 415 of FIG. 27, the carrier wafer 220 is adhered to the surface of the heat-generating device to form a package 100.

Referring now to FIG. 28, some examples of heat-generating devices are shown. An interposer 560 is shown here that includes a substrate 562 having through-substrate vias (TSVs) 570 extending between a first side 564 and a second side 566 of the substrate. A redistribution layer (RDL) 572 is formed over the first side 564 of the substrate. The RDL includes one or more layers of electrical interconnects that permit components to communicate with each other. The electrical interconnects are separated by a dielectric material. The RDL may be formed by several repeated steps of applying and patterning a dielectric layer, then applying and patterning a layer of electrically conductive materials. Bond pads 574 are illustrated on the surface of the RDL. Electrical connectors 568 are formed on the second side 566 of the substrate upon the TSVs 570. These may be, for example, lands, balls, pins, bumps, pillars, or other similar structures.

One or more chips are bonded to the interposer wafer substrate 560. Two different chips are illustrated here, for example a System-on-Chip (SOC) 576 and a memory chip 578. On an SoC, many electronic components are combined together on one common substrate. The SoC contains a semiconductor die, for example, a central processing unit (CPU) or a graphics processing unit (GPU). The memory chip may be, for example, high bandwidth memory (HBM). The chips 576, 578 are bonded, for example, through an interconnect layer 580 to the bond pads 574. An underfill material 582 fills any gaps between the chips 576, 578 and the interposer wafer substrate 560.

Three MEMS cooling devices 591, 592, 593 are illustrated in FIG. 28. The first MEMS cooling device 591 is attached to the interposer 560 itself, where passive devices such as resistors or inductors might generate heat. The second MEMS cooling device 592 is attached to the SoC 576. The CPU and GPU contained therein generate significant heat. The third MEMS cooling device 593 is attached to the memory chip 578, which can generate heat. It is noted that the MEMS cooling device is attached to a surface of the heat-generating device, but does not have to cover the entire surface to which it is attached.

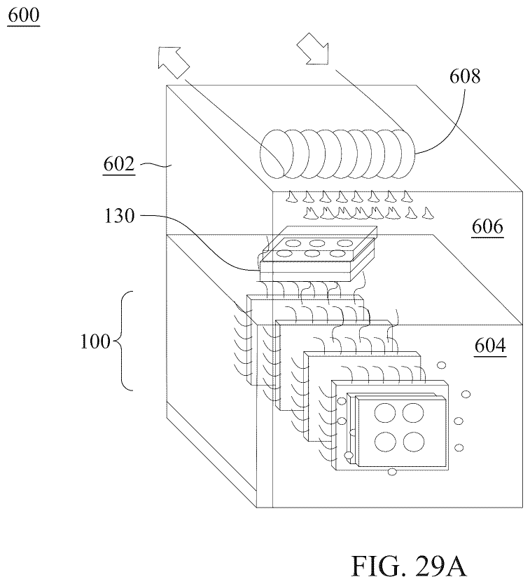

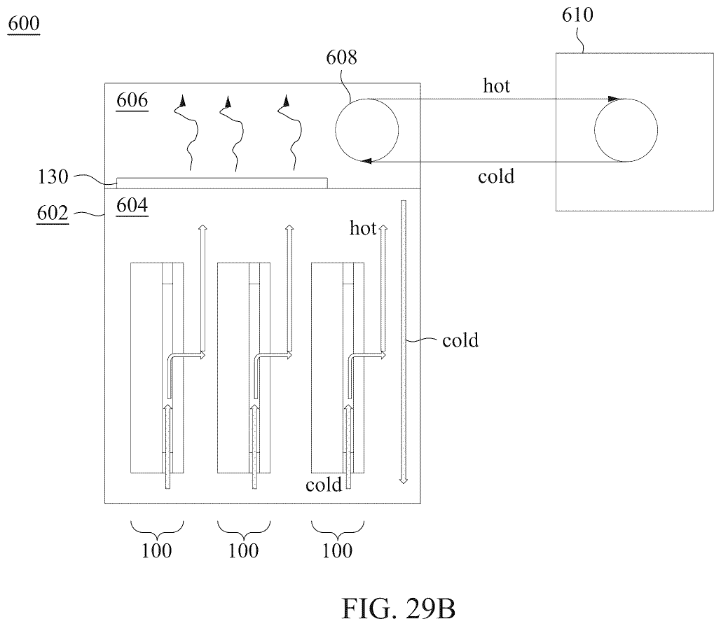

Next, FIG. 29A and FIG. 29B are different views of a liquid cooling system, and in particular a dual-phase immersion cooling system 600. As illustrated here, the cooling system includes a housing 602 in which a cooling liquid 604 is placed. Three packages 100 formed by the combination of a heat-generating device and a MEMS cooling device are shown as being placed within the housing, and in particular within the cooling liquid. Also illustrated is a MEMS cooling device 130 that floats upon the cooling liquid. The housing also contains an airspace 606 at the top, which includes a condenser coil 608. In particular embodiments, the cooling liquid is a dielectric liquid which is not electrically conductive, but is thermally conductive.

In operation, the packages 100 generate heat. The dielectric liquid eventually boils and turns into a gas. The phase change absorbs additional energy due to the heat of vaporization. The vapor condenses on the condenser coil 608, and returns to a liquid within the housing. A coolant within the condenser coil absorbs the heat energy and transfers the heat energy out of the housing and to a heat exchanger 610, where the heat is removed from the coolant. The coolant is then recycled to the condenser coil. Arrows are present to show fluid flow and temperature.

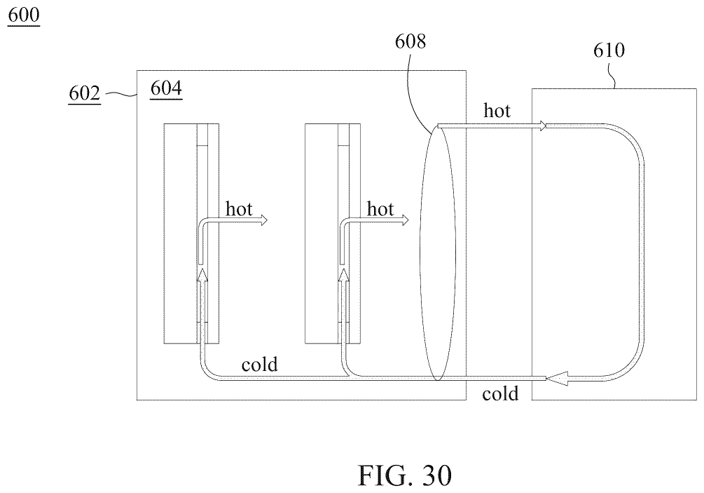

FIG. 30 is an illustration of a single-phase immersion cooling system 601. The system has the same components as the dual-phase system, but the cooling liquid fills the entire housing, and no airspace is present at the top. Otherwise, the system operates in the same manner.

Referring back to FIG. 27, then, as indicated in step 420, the package is placed in the housing 602 of FIG. 29B or FIG. 30. In step 425 of FIG. 27, the housing 602 is filled with a cooling liquid, such as a dielectric liquid, above the level of the package 100. These steps may be reversed as desired. Alternatively or in addition, in step 430 of FIG. 27 and as illustrated in FIG. 28B, a MEMS cooling device 130 may float at or near the surface 605 of the cooling liquid, above the heat-generating devices 110.

In operation, the heat-generating devices create heat energy that is absorbed by the cooling fluid/liquid. This may cause currents within the cooling liquid, or the formation of bubbles. As indicated in step 435 of FIG. 27, the MEMS actuator vibrates. This vibration may occur naturally due to liquid flow or other physical phenomena, or an insulated electrical cable may be connected to the MEMS actuator to induce vibration. Referring back to the arm array 198 of FIG. 1D, the arms 206, 216 can be moved in the X-axis, Y-axis, or Z-axis, and the direction of movement can be controlled. Vortices can be formed around the center of the actuator, which also increases the rate of fluid flow past the heat-generating device.

Due to the vibration, as indicated in step 440 of FIG. 27, cooling fluid flows past the heat-generating device at a higher rate (e.g. gallons/minute) compared to the situation in which the MEMS actuator is not present. The bubbles or liquid currents will pass through the holes of the carrier wafer and are pulled through the MEMS actuator.

If the system is a dual-phase system as illustrated in FIG. 29A, the cooling fluid boils, as indicated in optional step 445 of FIG. 27. As indicated in step 450 of, heat is transferred from the cooling fluid to the coolant in the condenser 608. Then, as indicated in step 455 of FIG. 27, heat is removed from the coolant in the heat exchanger 610. Finally, as indicated in step 460, the coolant is recycled back to the condenser 608.

The structures of the present disclosure have several advantages. Initially, cooling performance is improved. It is estimated that operating temperatures of heat-generating devices may be reduced from, for example, 55° C. to 60° C. without the MEMS cooling device down to 25° C. with the MEMS cooling device. The carrier wafer allows bubbles/liquid currents to pass through and drive the MEMS actuator vibration.

Some embodiments of the present disclosure thus relate to methods for making a carrier wafer. A first mask is formed upon a first side of a substrate. The first mask exposes an intermediate region between a perimeter region and a central region of the substrate. At least one cavity is then formed in the intermediate region in the substrate. A second mask is then formed upon the first side of the substrate. The second mask exposes one or more hole regions in the intermediate region. Etching is performed through the hole regions to form one or more holes that extend through the substrate to a second side of the substrate and obtain the carrier wafer.

Other embodiments disclosed herein relate to alternative methods of making a carrier wafer. A first mask is formed upon a first side of a substrate. The first mask exposes an intermediate region and the central region of the substrate. A first step is then formed in the central region, and the thickness of the intermediate region is reduced. A second mask is formed that exposes the intermediate region and a smaller portion of the central region. A plateau is formed in the central region, and the thickness of the intermediate region is reduced again. This may be repeated to form multiple plateaus. Another mask is formed that exposes inner portions of each plateau. Etching is then performed to form trenches from the inner portion, and define steps from the outer portion of each plateau. The same mask or another mask upon the first side of the substrate exposes one or more hole regions in the intermediate region. Etching is performed through the substrate in the exposed hole region(s) to form one or more holes that extend through the substrate to a second side of the substrate and obtain the carrier wafer.

Still further embodiments disclosed herein relate to alternative methods of making a carrier wafer. A first mask is formed upon a first side of a substrate. The first mask exposes an intermediate region and the central region of the substrate. A sloped sidewall is then formed in the central region, along with a cavity in the intermediate region. Another mask is formed that exposes trench regions in the central region. Etching is then performed to form trenches and define steps from the remaining portions of the sloped sidewall. The same mask or another mask upon the first side of the substrate exposes one or more hole regions in the intermediate region. Etching is performed through the substrate in the exposed hole region(s) to form one or more holes that extend through the substrate to a second side of the substrate and obtain the carrier wafer.

Also described in various embodiments herein are carrier wafers. A substrate has an intermediate region between a perimeter region and a central region of the substrate. The intermediate region has a thickness which is less than a thickness of the perimeter region. At least one cavity is present in the intermediate region in a first side of the substrate. One or more holes in the at least one cavity extend through the substrate to a second side of the substrate and obtain the carrier wafer.

Additional embodiments of the present disclosure relate to methods of making a MEMS cooling device. A MEMS actuator is bonded to a carrier wafer having one or more holes as described herein. Various embodiments of the MEMS cooling device itself are also disclosed.

Also described in various embodiments herein are methods of using a MEMS cooling device, or cooling a heat-generating device. The MEMS cooling device includes an actuator and a carrier wafer as previously described. The MEMS cooling device may be attached to the surface of a heat-generating device to form a package. Various embodiments of the package itself are also disclosed. The heat-generating device may be placed within a housing containing a cooling fluid, such as a dielectric liquid. A MEMS cooling device may also be floated upon the cooling fluid. When operated, the MEMS cooling device increases the rate at which the cooling fluid flows past the heat-generating device, thus further cooling the heat-generating device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for cooling a heat-generating device, comprising:
receiving a cooling device comprising an actuator and a carrier wafer;
wherein the carrier wafer comprises one or more holes that extend through a substrate from a first side to a second side of the substrate; and
wherein the first side of the carrier wafer is bonded to the actuator;
adhering the second side of the carrier wafer substrate to a surface of the heat-generating device to form a package; and
placing the package in a cooling fluid;
wherein the cooling fluid can flow between the second side of the carrier wafer substrate and the surface of the heat-generating device.

2. The method of claim 1, wherein the cooling fluid is a dielectric liquid.

3. The method of claim 1, wherein the heat-generating device is an interposer, high-bandwidth memory, a CPU, or a GPU.

4. The method of claim 1, wherein the one or more holes in the carrier wafer are located in an intermediate region of the carrier wafer.

5. The method of claim 4, wherein a central region of the carrier wafer includes a plurality of steps extending downwards towards the intermediate region

6. The method of claim 5, wherein each step has a height of about 2 μm to about 3 μm, and has a cross-sectional length of about 2 μm to about 3 μm.

7. The method of claim 4, wherein the intermediate region of the carrier wafer has a thickness that is less than a thickness of a perimeter region of the carrier wafer; or
wherein the carrier wafer further comprises at least one sidewall with one or more openings in a perimeter region of the substrate.

8. The method of claim 1, wherein the one or more holes are formed in at least one cavity in the carrier wafer.

9. The method of claim 9, wherein the at least one cavity has a depth of about 10 μm or greater, or has a length of about 20 μm or greater.

10. The method of claim 1, wherein the one or more holes independently have a diameter of about 2 μm to about 10 μm; or
wherein the one or more holes include a first hole and a second hole that have different surface areas or different shapes in a plan view.

11. The method of claim 1, wherein the carrier wafer has a length of about 30 μm or greater, and has a width of about 30 μm or greater.

12. A cooling device comprising an actuator bonded to a substrate, wherein the substrate comprises;
an intermediate region between a perimeter region and a central region of the substrate, wherein the intermediate region has a thickness which is less than a thickness of the perimeter region;
at least one cavity in the intermediate region in a first side of the substrate; and
one or more holes in the at least one cavity that extend through the substrate to a second side of the substrate.

13. The cooling device of claim 12, further comprising at least one sidewall with one or more openings in the perimeter region of the substrate.

14. The cooling device of claim 12, further comprising a plurality of steps in the central region of the substrate that extend downwards towards the intermediate region.

15. The cooling device of claim 14, wherein a top step of the central region is level with an upper surface of the perimeter region.

16. A method for making a carrier wafer, comprising:
forming a first mask upon a first side of a substrate, the first mask exposing an intermediate region between a perimeter region and a central region of the substrate;
forming at least one cavity in the intermediate region in the substrate;
forming a second mask upon the first side of the substrate, the second mask exposing one or more hole regions in the intermediate region;
etching through the one or more hole regions to form one or more holes that extend through the substrate to a second side of the substrate and obtain the carrier wafer.

17. The method of claim 16, further comprising, prior to forming the first mask:
forming an initial mask upon the first side of the substrate, the initial mask exposing the intermediate region and at least one opening region in the perimeter region of the substrate; and
etching to reduce an initial thickness of the intermediate region and form at least one sidewall with one or more openings in the perimeter region of the substrate;
wherein an intermediate thickness of the intermediate region is less than an initial thickness of the perimeter region.

18. The method of claim 16, further comprising:
patterning the central region of the substrate to form a plurality of steps extending downwards towards the intermediate region.

19. The method of claim 18, wherein the plurality of steps is formed by:
forming a first step and a first plateau located below the first step; and
forming a trench in the first plateau to define a second step.

20. The method of claim 18, wherein the plurality of steps is formed by:
forming a sloped sidewall; and
forming a trench in the sloped sidewall to define a first step and a second step.
